(19) United States
(12) Patent Application Publication
(10) Pub. No.: US 2026/0214944 A1
(43) Pub. Date: Jul. 23, 2026

(54) THIN FILM TRANSISTOR AND MANUFACTURING METHOD THEREOF, DISPLAY PANEL

(71) Applicants: Yungu (Gu’an) Technology Co., Ltd., Langfang (CN); Hefei Visionox Technology Co., Ltd., Hefei (CN)

(72) Inventors: Fa-Hsyang CHEN, Langfang (CN); Guowen YAN, Langfang (CN); Yinghai MA, Langfang (CN); Xiang LIU, Langfang (CN); Junfeng LI, Langfang (CN)

(73) Assignees: Yungu (Gu’an) Technology Co., Ltd., Langfang (CN); Hefei Visionox Technology Co., Ltd., Hefei (CN)

(21) Appl. No.: 19/567,226

(22) Filed: Mar. 15, 2026

Related U.S. Application Data
(63) Continuation of application No. PCT/CN2024/095721, filed on May 28, 2024.

(30) Foreign Application Priority Data
Sep. 20, 2023 (CN) 202311219272.6

(51) Int. Cl. H10D 30/67; H10D 30/01

(52) U.S. Cl. CPC H10D 30/6755; H10D 30/0312; H10D 30/6733

(57) ABSTRACT

The present disclosure provides a thin film transistor, a preparation method thereof, an array substrate, and a display panel. The thin film transistor includes a substrate, and an active layer and a first gate electrode located on the substrate. The active layer includes a first film layer and a second film layer stacked on the substrate, the second film layer is located between the first film layer and the first gate electrode, the first film layer and the second film layer are semiconductor film layers, a mobility of the second film layer is lower than a mobility of the first film layer, and a roughness of the second film layer is less than a roughness of the first film layer.

### CROSS-REFERENCE TO RELATED APPLICATIONS

This application is a continuation of International Application No. PCT/CN2024/095721 filed on May 28, 2024, which claims priority to Chinese Patent Application No. 202311219272.6, filed on Sep. 20, 2023, entitled “Thin Film Transistor and Manufacturing Method Thereof, Display Panel”, which is incorporated herein by reference in its entirety.

### FIELD

The present disclosure relates to the field of display technology, and in particular, to a thin film transistor and a manufacturing method thereof, and a display panel.

### BACKGROUND

With the development of information technology, the usage rate of electronic display products in daily life is increasing. Thin film transistors are the main switching elements in the drive circuits of electronic display products. However, the active layer in current thin film transistors, limited by its own structural design and formation process, struggles to simultaneously ensure film formation quality, high mobility, and high stability, thereby restricting further improvement in the performance of thin film transistors.

### SUMMARY

An embodiment of the present disclosure provides a thin film transistor. The thin film transistor includes a substrate, and an active layer and a first gate electrode located on the substrate. The active layer includes a first film layer and a second film layer stacked on the substrate. The second film layer is located between the first film layer and the first gate electrode. The first film layer and the second film layer are semiconductor film layers. The mobility of the second film layer is lower than the mobility of the first film layer, and the roughness of the second film layer is less than the roughness of the first film layer.

In the above solution, the first film layer has relatively high mobility. Therefore, when the thin film transistor operates, carriers accumulate on the surface of the first film layer facing the first gate electrode. The second film layer with low roughness can improve this surface, avoiding surface defects to reduce the leakage current of the thin film transistor, thereby improving its performance.

An embodiment of the present disclosure provides a display panel. The display panel includes the thin film transistor according to the embodiments described above.

An embodiment of the present disclosure provides a method for manufacturing a thin film transistor. The manufacturing method includes: providing a substrate; depositing a first semiconductor material film layer having a first mobility on the substrate at a first film formation rate, and depositing a second semiconductor material film layer having a second mobility at a second film formation rate, and the first mobility is greater than the second mobility, and the first film formation rate is greater than the second film formation rate, and the roughness of the second semiconductor material film layer is less than the roughness of the first semiconductor material film layer; patterning the first semiconductor material film layer and the second semiconductor material film layer to respectively form a first film layer and a second film layer; depositing a first conductive material film on the substrate, and patterning the first conductive material film to form a first gate electrode, and the second film layer is formed between the first film layer and the first gate electrode.

### BRIEF DESCRIPTION OF THE DRAWINGS

FIG. 1 is a cross-sectional view of a thin film transistor provided by an embodiment of the present disclosure.

FIG. 2 is a cross-sectional view of another thin film transistor provided by an embodiment of the present disclosure.

FIG. 3 is a cross-sectional view of another thin film transistor provided by an embodiment of the present disclosure.

FIG. 4 is a cross-sectional view of another thin film transistor provided by an embodiment of the present disclosure.

FIG. 5 is a cross-sectional view of an array substrate provided by an embodiment of the present disclosure.

FIG. 6 is a schematic plan view of a display panel provided by an embodiment of the present disclosure.

FIG. 7 is a cross-sectional view of the display panel shown in FIG. 6 taken along line M-N.

FIG. 8 is a flowchart of a method for manufacturing a thin film transistor provided by an embodiment of the present disclosure.

FIG. 9 is a flowchart of a method for manufacturing a thin film transistor provided by another embodiment of the present disclosure.

FIG. 10 is a flowchart of a method for manufacturing a thin film transistor provided by yet another embodiment of the present disclosure.

FIG. 11 is a flowchart of a method for manufacturing a thin film transistor provided by yet another embodiment of the present disclosure.

FIG. 12 is a flowchart of a method for manufacturing a thin film transistor provided by yet another embodiment of the present disclosure.

FIG. 13 is a flowchart of a method for manufacturing a thin film transistor provided by yet another embodiment of the present disclosure.

FIG. 14 is a flowchart of a method for manufacturing a thin film transistor provided by yet another embodiment of the present disclosure.

FIG. 15 is a flowchart of a method for manufacturing a thin film transistor provided by yet another embodiment of the present disclosure.

FIG. 16 to FIG. 20 are process diagrams of a method for manufacturing a thin film transistor provided by an embodiment of the present disclosure.

FIG. 21A and FIG. 21B are simulation effect diagrams of a semiconductor stack under two manufacturing processes provided by an embodiment of the present disclosure.

FIG. 22A and FIG. 22B are simulation effect diagrams of a semiconductor film layer under two manufacturing processes provided by an embodiment of the present disclosure.

### DETAILED DESCRIPTION

In a thin film transistor, the quality of the channel surface affects mobility. If there are defects on the channel surface, such as high roughness, it indicates poor flatness of the channel surface. This means the thickness of the channel for carrier transport is unevenly distributed, leading to degradation of the electrical properties and reliability of the channel. Furthermore, high roughness of a film layer indicates poor regularity in the arrangement of atoms, molecules, etc., on its surface, resulting in relatively low structural strength and poor barrier effect against external substances. Therefore, when preparing layers such as dielectric layers in a thin film transistor, if harmful ions invade the channel, it can also degrade the electrical properties and reliability of the channel.

Embodiments of the present disclosure provide a thin film transistor and a manufacturing method thereof, and a display panel, to at least solve the above problems. The thin film transistor includes a substrate, and an active layer and a first gate electrode located on the substrate. The active layer includes a first film layer and a second film layer stacked on the substrate. The second film layer is located between the first film layer and the first gate electrode. The first film layer and the second film layer are semiconductor film layers. The mobility of the second film layer is lower than the mobility of the first film layer, and the roughness of the second film layer is less than the roughness of the first film layer. In this design, the first film layer has relatively high mobility. Therefore, when the thin film transistor operates, carriers accumulate on the surface of the first film layer facing the first gate electrode. The second film layer with low roughness can improve this surface, avoiding surface defects to reduce the leakage current of the thin film transistor, thereby improving its performance. Additionally, the second film layer with low roughness has a strong barrier effect against ions, thereby protecting the first film layer.

Below, the structures involved in the thin film transistor and its preparation method, as well as the display panel according to at least one embodiment of the present disclosure, are described in conjunction with the accompanying drawings. In these embodiments, a spatial rectangular coordinate system is established based on the surface where the substrate of the thin film transistor is located (e.g., the display surface of the display panel) to describe the positions of various structures in the thin film transistor, the array substrate, and the display panel. In this spatial rectangular coordinate system, the X-axis and Y-axis are parallel to the substrate, and the Z-axis is perpendicular to the substrate.

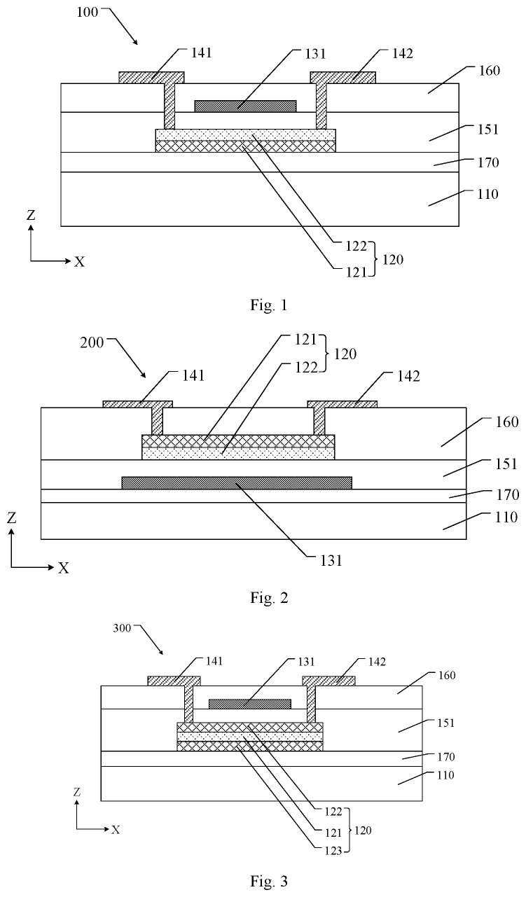

As shown in FIG. 1, the thin film transistor 100 includes an active layer 120 and a first gate electrode 131, with the first gate electrode 131 spaced apart from the active layer 120. The substrate 110 is used to support the active layer 120 and the first gate electrode 131. By controlling the voltage on the first gate electrode 131, a voltage fluctuation can be induced in the active layer 120, generating carriers and thereby forming a current channel. In this way, the switching of the thin film transistor 100 and the degree to which it is turned on can be controlled.

The active layer 120 includes a first film layer 121 and a second film layer 122 stacked together. The first film layer 121 is formed from a semiconductor material with high mobility, and the second film layer 122 is formed from a semiconductor material with low mobility, and the surface of the first film layer 121 in contact with the second film layer 122 serves as the main channel for two-dimensional electron gas (carriers). The roughness of the second film layer 122 is less than that of the first film layer 121, and the flatness of the second film layer 122 is higher than that of the first film layer 121. During the film formation process, the high degree of planarization of the surface of the second film layer 122 can improve the surface defects of the first film layer 121, ensuring the electrical properties and stability of the active layer. Additionally, the second film layer 122 with high flatness provides better barrier effects against ions, thereby protecting the first film layer 121.

Based on the thin film transistor shown in FIG. 1, the surface of the first film layer 121 in contact with the second film layer 122 serves as the channel for carrier flow. Therefore, the thickness of this channel (along the direction perpendicular to the plane where the active layer 120 is located, i.e., the direction of the Z-axis in FIG. 1) is very small. Correspondingly, the flatness of this surface is related to the uniformity of the channel thickness. If the roughness of this surface is low, the flatness is high, and the thickness of the channel is relatively more uniform. The thickness of this channel is not equal to the dimension of the first film layer 121 along the Z-axis direction.

In the embodiments of the present disclosure, “roughness” represents the microscopic flatness (or undulation degree) of the film layer surface, i.e., the amplitude of the undulation fluctuations (e.g., the distance between peaks and valleys). Therefore, it can be expressed in units of length (e.g., nanometers, micrometers, etc.). High roughness indicates that the arrangement of atoms, molecules, or lattice structures on the film layer surface is loose, with large undulations. Correspondingly, low roughness indicates that the arrangement of atoms, molecules, or lattice structures on the film layer surface is relatively regular and dense, with small undulations, providing a higher barrier effect against the intrusion of external substances.

When evaluating roughness, it can also be obtained based on characteristics such as fluctuation spacing (e.g., the spacing between peaks or valleys of undulations) and microscopic shapes. In such cases, roughness can be comprehensively calculated based on characteristics such as amplitude (height), spacing, and shape.

For example, as shown in FIG. 1, the thin film transistor 100 may further include a source electrode 141 and a drain electrode 142, with the source electrode 141 and the drain electrode 142 connected to the active layer 120. The active layer 120 can be divided into a channel region, a source region, and a drain region. The channel region is located between the source region and the drain region and corresponds to the first gate electrode 131. That is, the orthographic projection of the channel region on the substrate falls within the orthographic projection of the first gate electrode 131 on the substrate, or the orthographic projection of the channel region on the substrate coincides with the orthographic projection of the first gate electrode 131 on the substrate. The source region and the drain region may be located at both ends of the active layer 120. The source region is used to connect (electrically connect, e.g., ohmic contact) to the source electrode 141, and the drain region is used to connect (electrically connect, e.g., ohmic contact) to the drain electrode 142. For example, after a voltage is applied to the first gate electrode 131, the channel opens (depending on the material of the active layer, the channel state may be opposite in this case, possibly changing from open to closed), and the current (electrical signal) from the source electrode 141 is conducted through the active layer 120 to the drain electrode 142.

For example, in at least one embodiment of the present disclosure, as shown in FIG. 1, the thin film transistor 100 may further include a first gate insulating layer 151 and an interlayer dielectric layer 160 to define the various structures in the thin film transistor 100. For example, the first gate insulating layer 151 is located between the first gate electrode 131 and the active layer 120 to separate the first gate electrode 131 and the active layer 120. The interlayer dielectric layer 160 is located between the source-drain electrode layer (including the source electrode 141 and the drain electrode 142) and the first gate electrode 131 to separate the source-drain electrode layer and the first gate electrode 131.

For example, in at least one embodiment of the present disclosure, as shown in FIG. 1, the thin film transistor 100 may further include a buffer layer 170 located between the substrate 110 and the active layer 120. The buffer layer 170 can block harmful ions from intruding from the substrate 110 into the active layer 120.

In the embodiments of the present disclosure, as long as it is ensured that the roughness of the second film layer is less than that of the first film layer and the mobility of the second film layer is higher than that of the first film layer, there are no restrictions on the specific preparation processes or materials of the first film layer and the second film layer. Below, exemplary descriptions are provided for different choices of preparation processes and specific materials for the first film layer and the second film layer, as well as the structure of the thin film transistor under the corresponding choices.

In some embodiments of the present disclosure, the first film layer and the second film layer are formed of semiconductor film layers deposited by physical vapor deposition, and the power of the physical vapor deposition corresponding to the semiconductor film layer used to form the first film layer is greater than the power of the physical vapor deposition corresponding to the semiconductor film layer used to form the second film layer, and the roughness of the second film layer is less than the roughness of the first film layer. The film formation rate of the film layer formed by physical vapor deposition at low power is low, enabling the film layer to have lower roughness. Therefore, by controlling the power of the physical vapor deposition, the difference in roughness between the first film layer and the second film layer can be controlled. For example, the power of the physical vapor deposition for forming the first semiconductor material film layer may be 4 KW to 6 KW, and the power of the physical vapor deposition for forming the second semiconductor material film layer may be 2 KW to 4 KW.

In other embodiments of the present disclosure, the first film layer is formed of a semiconductor film layer deposited by physical vapor deposition, and the second film layer is formed of a semiconductor film layer deposited by atomic layer deposition, and the roughness of the second film layer is less than the roughness of the first film layer. For example, the rate of forming the first film layer by physical vapor deposition is 80 Å/s to 120 Å/s, and the rate of forming the second film layer by atomic layer deposition is 20 Å/s to 60 Å/s.

Atomic Layer Deposition (ALD) is a surface deposition technique that can prepare high-quality nanomaterials by depositing atomically thin films layer by layer on the material surface. The technical advantages of ALD include: high precision control; controlling the thickness and composition of each layer, thereby precisely controlling the thickness and properties of the film; forming a uniform film on the structural surface, thereby improving the quality and stability of the film; and being performed at low temperatures, reducing the generation of impurities, thereby improving the purity of the film. Therefore, the film layer formed by ALD has good uniformity, a uniform film layer surface, and a low risk of surface defects.

For example, the roughness of the first film layer is greater than 1 nanometer, and the roughness of the second film layer is not greater than 1 nanometer. For example, further, the roughness of the second film layer is not greater than 0.8 nanometers. The actual roughness of the first film layer and the second film layer can be designed according to specific process requirements and is not limited to the above numerical ranges, as long as the degree of roughness of the second film layer can achieve the effect of improving the surface of the first film layer.

For example, in the embodiments of the present disclosure, when the first film layer has high mobility and high roughness, there is no limitation on the material of the first film layer, and it can be determined according to actual process requirements. For example, the material of the first film layer includes at least one of In, Ga, Zn, and Sn. For example, in one embodiment, the material of the first film layer is one of IGZO, IGZTO, IZO, and IGO. For example, further, the mobility of the first film layer is not less than 20 cm²/Vs.

For example, in the embodiments of the present disclosure, when the second film layer has low mobility and low roughness, there is no limitation on the material of the second film layer, and it can be determined according to actual process requirements. For example, the material of the second film layer includes at least one of In, Ga, and Zn. For example, in one embodiment, the material of the second film layer is IGZO. For example, further, the mobility of the second film layer is not greater than 15 cm²/Vs.

For example, as shown in FIG. 1, the first film layer 121 and the second film layer 122 are in contact with each other, and the first film layer 121 and the second film layer 122 can be prepared in the same patterning process to reduce the preparation process flow of the active layer 120. In this case, the patterns of the first film layer 121 and the second film layer 122 substantially coincide, that is, the orthographic projection of the first film layer 121 on the substrate 110 coincides with the orthographic projection of the second film layer 122 on the substrate 110.

In the embodiments of the present disclosure, when the first film layer is a semiconductor layer and the thin film transistor includes only one gate electrode (the first gate electrode), the thin film transistor can be configured as a top-gate thin film transistor or as a bottom-gate thin film transistor, as detailed below.

For example, in some embodiments of the present disclosure, as shown in FIG. 1, when the first film layer 121 is a semiconductor layer, the first film layer 121 is located between the second film layer 122 and the substrate 110, that is, the thin film transistor 100 is a top-gate thin film transistor.

Both ends of the first film layer need to be doped (e.g., heavily doped) for conductorization to facilitate ensuring electrical connection between the active layer and the source and drain electrodes. In the case where the thin film transistor is a top-gate thin film transistor, the design thickness of the second film layer can be reduced to ensure that the arrangement of the second film layer does not adversely affect the doping of the first film layer. For example, the thickness of the second film layer is less than the thickness of the first film layer.

For example, the thickness of the first film layer is 50 to 500 Å, such as 100 Å, 200 Å, 300 Å, 400 Å, etc., and/or the thickness of the second film layer is 10 to 100 Å, such as 20 Å, 40 Å, 60 Å, 80 Å, etc.

For example, in other embodiments of the present disclosure, as shown in FIG. 2, when the first film layer 121 is a semiconductor layer, the second film layer 122 is located between the first film layer 121 and the substrate 110, that is, the thin film transistor 200 is a bottom-gate thin film transistor.

For example, as shown in FIG. 2, when the thin film transistor 200 is a bottom-gate thin film transistor, the orthographic projection of the active layer 120 on the substrate 110 is located within the orthographic projection of the first gate electrode 131 on the substrate 110. In this way, adverse effects of the arrangement of the first gate electrode 131 on the flatness of the active layer 120 can be avoided. Additionally, the first gate electrode 131 can block light transmitted from the substrate 110 side to reduce the issue of photogenerated carriers in the active layer 120. Furthermore, the first gate electrode 131 can block harmful ions invading from the substrate 110 into the active layer 120.

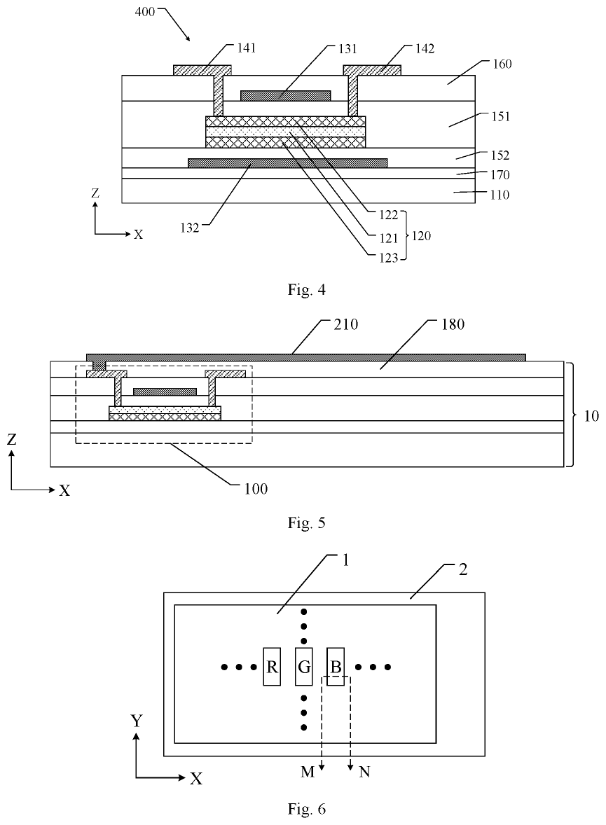

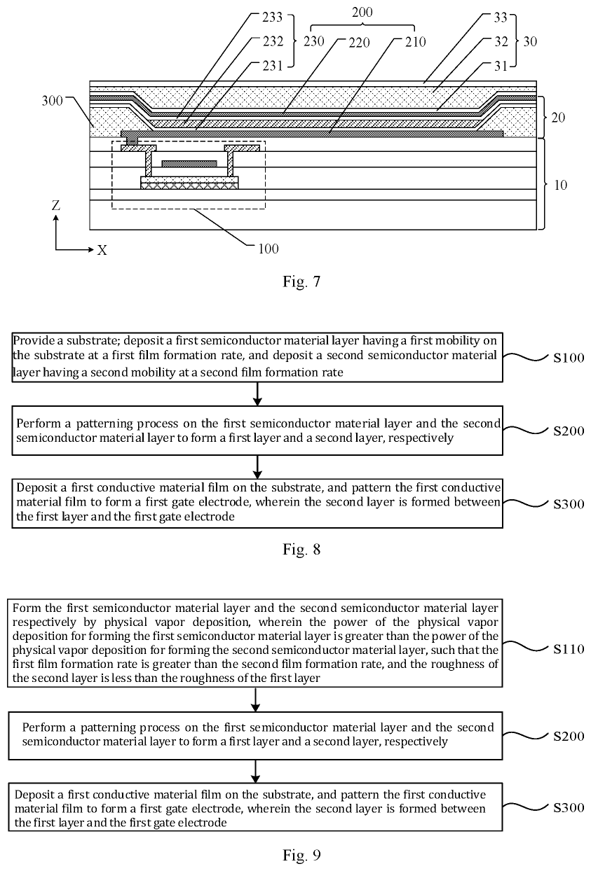

In at least one embodiment of the present disclosure, as shown in FIG. 3, the active layer 120 may further include a third film layer 123. The third film layer 123 is located on a side of the first film layer 121 away from the first gate electrode 131, and the third film layer 123 is made of a semiconductor material. The mobility of the third film layer 123 is lower than the mobility of the first film layer 121, and the roughness of the third film layer 123 is less than the roughness of the first film layer 121. In this way, the third film layer 123 and the second film layer 122 can protect the first film layer 121 from both sides to prevent harmful ions from other dielectric layers (e.g., the gate insulating layer) from intruding into the first film layer 121. The mobility of the third film layer is lower than the mobility of the first film layer; therefore, the first film layer is still used to form the channel. In some embodiments of the present disclosure, the first film layer and the third film layer are formed by physically vapor-deposited semiconductor film layers, and the power corresponding to the physical vapor deposition for the semiconductor film layer forming the first film layer is greater than the power corresponding to the physical vapor deposition for the semiconductor film layer forming the third film layer, and the roughness of the third film layer is less than the roughness of the first film layer. The film formation rate of the film layer formed by physical vapor deposition at low power is low, allowing the film layer to have higher roughness. Therefore, by controlling the power of the physical vapor deposition, the difference in roughness between the first film layer and the third film layer can be controlled. In other embodiments of the present disclosure, the first film layer is formed by a physically vapor-deposited semiconductor film layer, and the third film layer is formed by an atomic layer deposited semiconductor film layer, and the roughness of the third film layer is less than the roughness of the first film layer. For example, the roughness of the third film layer is not greater than 1 nanometer. For example, further, the roughness of the third film layer is not greater than 0.8 nanometers. For example, in the embodiments of the present disclosure, when the third film layer has low mobility and low roughness, the material of the third film layer is not limited and can be determined according to actual process requirements. For example, the material of the third film layer includes at least one of In, Ga, and Zn. For example, in one embodiment, the material of the third film layer is IGZO. For example, further, the mobility of the third film layer is not greater than 15 cm²/V·s. For example, in some embodiments of the present disclosure, as shown in FIG. 3, the third film layer 123 and the first film layer 121 can be prepared in the same patterning process to reduce the preparation process flow of the active layer 120. In this case, the orthographic projection of the third film layer 123 on the substrate 110 coincides with the orthographic projection of the first film layer 121 on the substrate 110. For example, further, the orthographic projections of the first film layer 121, the second film layer 122, and the third film layer 123 on the substrate 110 coincide, that is, the first film layer 121, the second film layer 122, and the third film layer 123 are formed in the same patterning process. In this way, contact between the first film layer 121 and other materials (e.g., photoresist) can be avoided, preventing contamination (e.g., ion intrusion). In at least one embodiment of the present disclosure, as shown in FIG. 4, the thin film transistor 400 can be designed as a dual-gate thin film transistor to improve the response speed of the thin film transistor. For example, the thin film transistor 400 may include a second gate electrode 132, and the second gate electrode 132 is located on a side of the active layer 120 away from the first gate electrode 131. For the first gate electrode 131 and the second gate electrode 132, the area of the one located between the active layer 120 and the substrate 110 is larger than the area of the active layer 120 to shield the active layer 120 and ensure the flatness of the active layer 120. Exemplarily, as shown in FIG. 4, the second gate electrode 132 is located between the active layer 120 and the substrate 110, and the orthographic projection of the active layer 120 on the substrate 110 is located within the orthographic projection of the second gate electrode 132 on the substrate 110. For example, as shown in FIG. 4, when the second gate electrode 132 is provided, the thin film transistor 100 may further include a second gate insulating layer 152 located between the active layer 120 and the second gate electrode 132. At least one embodiment of the present disclosure provides an array substrate. As shown in FIG. 5, the array substrate may include a driving circuit layer 10. The driving circuit layer includes a plurality of pixel driving circuits, each pixel driving circuit includes a plurality of thin film transistors 100, and at least one thin film transistor is the thin film transistor described in the above embodiments. For example, the pixel driving circuit may include a plurality of transistors TFT (thin film transistors), capacitors, etc., and may be formed in various forms such as 2T1C (i.e., 2 transistors (TFT) and 1 capacitor (C)), 3T1C, or 7T1C. The pixel driving circuit is connected to a light-emitting device (refer to the light-emitting device 200 in the following embodiments) to control the switching state and the light-emitting brightness of the light-emitting device. For example, in at least one embodiment of the present disclosure, as shown in FIG. 5, the array substrate may further include a planarization layer 180 and an anode 210 located on the planarization layer 180. A via hole is provided in the planarization layer 180. The pixel driving circuit is arranged corresponding to the anode 210, and a source electrode or a drain electrode of one thin film transistor in the pixel driving circuit is connected to the corresponding anode 210 through the via hole. At least one embodiment of the present disclosure provides a display panel. As shown in FIG. 6 and FIG. 7, the display panel includes a display functional layer 20 and the array substrate 10 described in the above embodiments. The display panel can be divided into a display area 1 and a border area 2 located on at least one side of the display area 1. A plurality of sub-pixels R, G, B are arranged in the display area 1. The display functional layer 20 is located on the array substrate 10 and includes a plurality of light-emitting devices 200. The light-emitting devices 200 are the physical light-emitting structures of the sub-pixels R, G, B. For example, the light-emitting devices 200 located in the sub-pixels R, G, and B are respectively designed to emit red light (R), green light (G), and blue light (B). For example, the light-emitting device 200 is connected to the pixel driving circuit in the array substrate 100.

The light-emitting device 200 may include an anode 210, a light-emitting functional layer 230, and a cathode 220 sequentially stacked on the array substrate. The light-emitting functional layer 230 may include a first common layer 231, a light-emitting layer 232, and a second common layer 233 sequentially stacked on the anode 210. For example, the first common layer 231 may include a hole injection layer, a hole transport layer, and may further include an electron blocking layer, etc. For example, the second common layer 233 may include an electron injection layer, an electron transport layer, and may further include a hole blocking layer, etc.

For example, as shown in FIG. 7, the display panel may further include a pixel defining layer 300. The pixel defining layer 300 includes a plurality of openings to define the positions of the light-emitting devices. For example, the light-emitting layer of each light-emitting device 200 is located within the opening.

For example, as shown in FIG. 7, the display panel may further include an encapsulation layer 30 covering the display functional layer 20 to protect the light-emitting device 200. For example, the encapsulation layer 30 may include a first inorganic encapsulation layer 31, an organic encapsulation layer 32, and a second inorganic encapsulation layer 33 sequentially stacked on the display functional layer 20.

For example, in an embodiment of the present disclosure, the display panel may further include functional structures such as a touch functional layer, a polarizer, a lens layer, and a cover plate located on the display side (e.g., on the encapsulation layer).

For example, in an embodiment of the present disclosure, the display panel may be any product or component with a display function, such as a television, digital camera, mobile phone, watch, tablet computer, laptop computer, or navigator.

At least one embodiment of the present disclosure provides a method for preparing the thin-film transistor mentioned in the above embodiments. As shown in FIG. 8, the preparation method may include the following steps S100 to S300.
S100: Provide a substrate; deposit a first semiconductor material layer having a first mobility on the substrate at a first film formation rate, and deposit a second semiconductor material layer having a second mobility at a second film formation rate.

The first mobility is greater than the second mobility, and the first film formation rate is greater than the second film formation rate, and the roughness of the second semiconductor material layer is less than the roughness of the first semiconductor material layer.
S200: Perform a patterning process on the first semiconductor material layer and the second semiconductor material layer to form a first layer and a second layer, respectively.
S300: Deposit a first conductive material film on the substrate, and pattern the first conductive material film to form a first gate electrode, and the second layer is formed between the first layer and the first gate electrode.

In this preparation method, the first layer has a relatively high mobility. Therefore, when the thin-film transistor operates, carriers will gather on the surface of the first layer facing the first gate electrode. The second layer with high roughness can improve this surface to avoid surface defects, thereby enhancing the performance of the thin-film transistor.

For example, as shown in FIG. 9, in some embodiments of the present disclosure, the aforementioned step S100 may include:
S110: Form the first semiconductor material layer and the second semiconductor material layer respectively by physical vapor deposition, and the power of the physical vapor deposition for forming the first semiconductor material layer is greater than the power of the physical vapor deposition for forming the second semiconductor material layer, and the first film formation rate is greater than the second film formation rate, and the roughness of the second layer is less than the roughness of the first layer. Under this design, the specific materials and formation environment of the first layer and the second layer can be referred to the relevant descriptions in the aforementioned embodiments, and details are not repeated here.

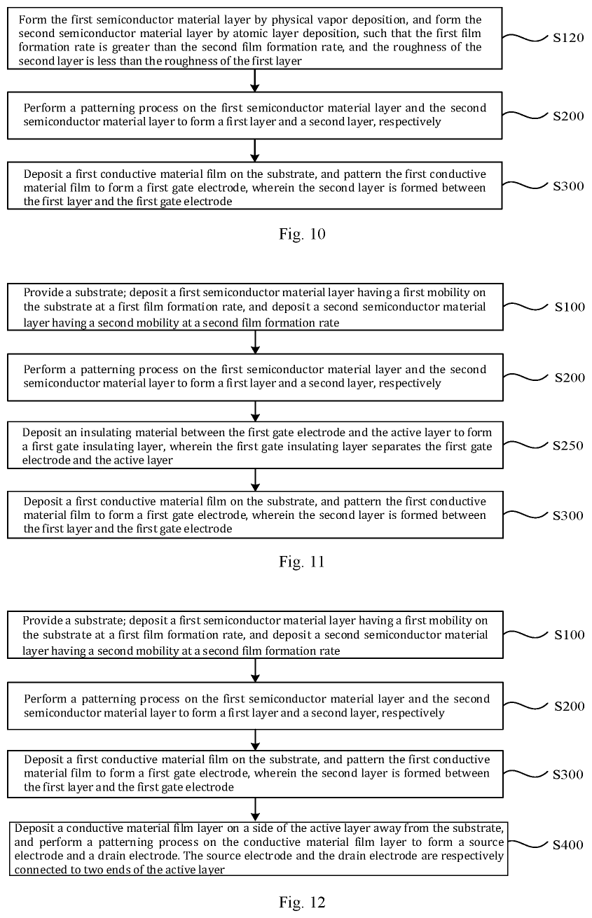

For example, as shown in FIG. 10, in other embodiments of the present disclosure, the aforementioned step S100 may include:
S120: Form the first semiconductor material layer by physical vapor deposition, and form the second semiconductor material layer by atomic layer deposition, and the first film formation rate is greater than the second film formation rate, and the roughness of the second layer is less than the roughness of the first layer. Under this design, the specific materials and formation environment of the first layer and the second layer can be referred to the relevant descriptions in the aforementioned embodiments, and details are not repeated here.

For example, as shown in FIG. 11, in at least one embodiment of the present disclosure, the preparation method may further include:
S250: Deposit an insulating material between the first gate electrode and the active layer to form a first gate insulating layer, and the first gate insulating layer separates the first gate electrode and the active layer. The positional relationship between the first gate insulating layer, the first gate electrode, and the active layer formed in this manner can be referred to the relevant descriptions in the aforementioned embodiments, and details are not repeated here.

For example, as shown in FIG. 12, the preparation method further includes:
S400: Deposit a conductive material film layer on a side of the active layer away from the substrate, and perform a patterning process on the conductive material film layer to form a source electrode and a drain electrode. The source electrode and the drain electrode are respectively connected to two ends of the active layer. The positional relationship between the source electrode, the drain electrode, the first gate electrode, and the active layer formed in this manner can be referred to the relevant descriptions in the aforementioned embodiments, and details are not repeated here.

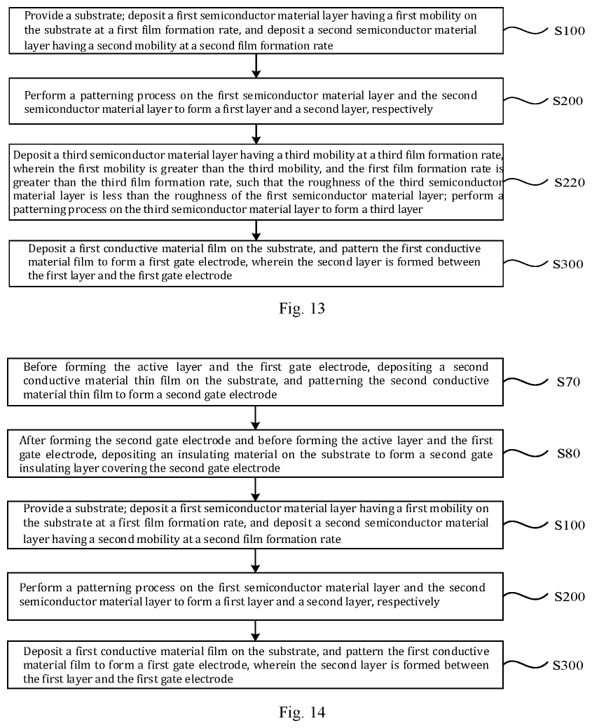

For example, as shown in FIG. 13, in at least one embodiment of the present disclosure, the preparation method may further include:
S220: Deposit a third semiconductor material layer having a third mobility at a third film formation rate, and the first mobility is greater than the third mobility, and the first film formation rate is greater than the third film formation rate, and the roughness of the third semiconductor material layer is less than the roughness of the first semiconductor material layer; perform a patterning process on the third semiconductor material layer to form a third layer. Under this design, the specific material and formation environment of the third layer can be referred to the relevant descriptions in the aforementioned embodiments, and details are not repeated here.

In the preparation method provided by at least one embodiment of the present disclosure, the second mobility is equal to the third mobility. For example, the second film formation rate is equal to the third film formation rate, and the roughness of the second layer and the third layer are equal. The mobility and roughness of the second layer and the third layer are equal. For example, the materials of the second layer and the third layer may also be the same to reduce the preparation cost of the thin-film transistor.

In at least one embodiment of the present disclosure, the preparation method may further include: after depositing the first semiconductor material layer, the second semiconductor material layer, and the third semiconductor material layer, simultaneously performing a patterning process on the first semiconductor material layer, the second semiconductor material layer, and the third semiconductor material layer to form a first film layer, a second film layer, and a third film layer, and an orthographic projection of the first film layer on the substrate, an orthographic projection of the second film layer on the substrate, and an orthographic projection of the third film layer on the substrate coincide. In this way, the preparation process cost of the active layer can be simplified. Furthermore, the second semiconductor material layer and the third semiconductor material layer can protect the first semiconductor material layer, thereby reducing the risk of contamination of the active layer, especially the first film layer therein, during the preparation process.

In at least one embodiment of the present disclosure, the preparation method may further include: depositing a second conductive material thin film on the substrate, and patterning the second conductive material thin film to form a second gate electrode, and the second gate electrode is formed on a side of the active layer opposite to the first gate electrode. For the structure of the thin film transistor formed as a dual-gate thin film transistor, reference may be made to the relevant descriptions in the foregoing embodiments, which will not be repeated here. Furthermore, based on different choices of whether the first gate electrode is located above or below the active layer, the preparation method for the second gate electrode may have different options, as detailed below.

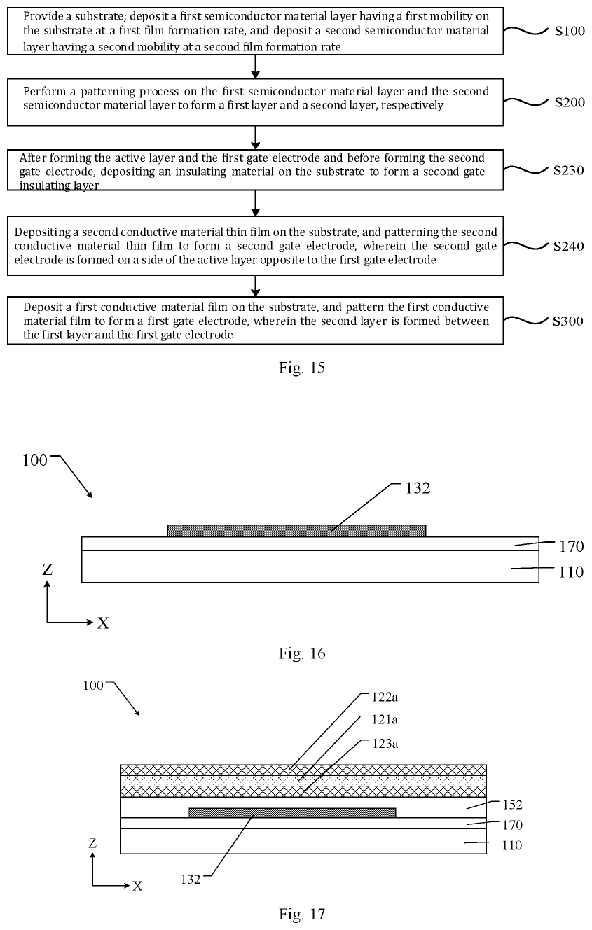

For example, as shown in FIG. 14, in some embodiments of the present disclosure, the first gate electrode is formed on a side of the active layer opposite to the substrate, and the preparation method further includes:
S70: before forming the active layer and the first gate electrode, depositing a second conductive material thin film on the substrate, and patterning the second conductive material thin film to form a second gate electrode.

For example, in other embodiments of the present disclosure, the preparation method may further include:
S80: after forming the second gate electrode and before forming the active layer and the first gate electrode, depositing an insulating material on the substrate to form a second gate insulating layer covering the second gate electrode.

In at least one embodiment of the present disclosure, as shown in FIG. 15, the preparation method may further include:
S240: after forming the first gate electrode and the active layer on the substrate, depositing a second conductive material thin film on the substrate, and patterning the second conductive material thin film to form a second gate electrode, and the second gate electrode is formed on a side of the active layer opposite to the first gate electrode.

For example, in other embodiments of the present disclosure, the preparation method may further include:
S230: after forming the active layer and the first gate electrode and before forming the second gate electrode, depositing an insulating material on the substrate to form a second gate insulating layer.

The positional relationship between the second gate insulating layer formed by this method and other structures in the thin film transistor can be referred to the relevant descriptions in the foregoing embodiments, which will not be repeated here.

Below, taking the preparation of the thin film transistor 400 as shown in FIG. 4 as an example, the process of the preparation method for the thin film transistor in at least one embodiment of the present disclosure is described, in one embodiment referring to the process steps shown in FIG. 16 to FIG. 20 below.

As shown in FIG. 16, a substrate 110 is provided, and an insulating material film layer and a conductive material thin film (the aforementioned second conductive material thin film) are sequentially deposited on the substrate 110. The insulating material film layer forms a buffer layer 170; a patterning process is performed on the conductive material thin film to form a second gate electrode 132.

In the embodiments of the present disclosure, the patterning process may be a photolithography patterning process, which may include, for example: applying a photoresist on a structural layer to be patterned, exposing the photoresist using a mask, developing the exposed photoresist to obtain a photoresist pattern, etching the structural layer using the photoresist pattern (in one embodiment wet etching or dry etching), and then in one embodiment removing the photoresist pattern. When the material of the structural layer includes a photoresist, the structural layer may be directly exposed using a mask to form the required pattern.

As shown in FIG. 16>to FIG. 17, an insulating material film layer is deposited on the substrate 110 with the second gate electrode 132 formed thereon to form a second gate insulating layer 152; then, a third semiconductor material film layer 123a, a first semiconductor material film layer 121a, and a second semiconductor material film layer 122a are sequentially deposited on the second gate insulating layer 152. The second semiconductor material film layer 122a and the third semiconductor material film layer 123a may be formed by atomic layer deposition, with a roughness not greater than 1 nanometer and a thickness ranging from 10 to 100 angstroms; the first semiconductor material film layer 121a may be formed by physical vapor deposition, with a roughness greater than 1 nanometer and a thickness ranging from 50 to 500 angstroms.

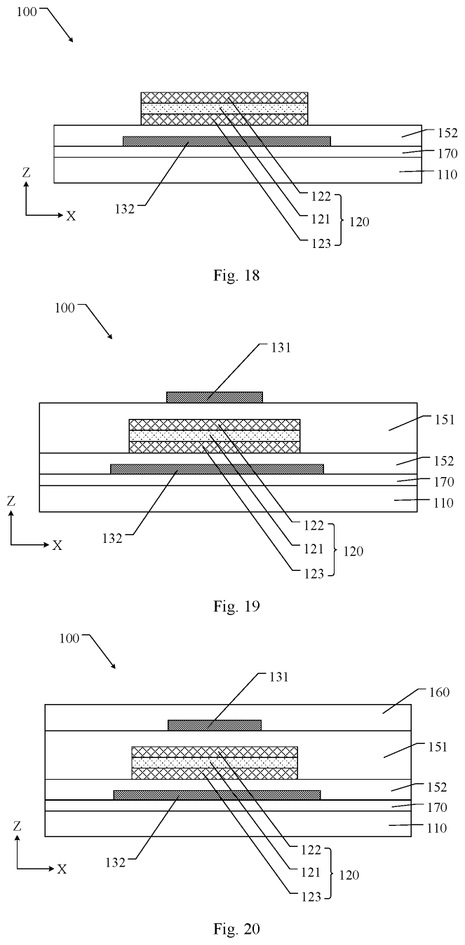

As shown in FIG. 17>to FIG. 18, a patterning process is performed on the first semiconductor material film layer 121a, the second semiconductor material film layer 122a, and the third semiconductor material film layer 123a to respectively form a first film layer 121, a second film layer 122, and a third film layer 123. The stacked first film layer 121, second film layer 122, and third film layer 123 constitute an active layer 120.

For example, in the step shown in FIG. 18, a doping process may be performed on both ends of the first film layer 121 (the source region and drain region respectively connected to the source electrode and drain electrode) through the second film layer 122, and both ends of the first film layer 121 become conductive.

In some embodiments of the present disclosure, after forming a gate electrode (e.g., the first gate electrode 131 shown in FIG. 19 below) on a side of the active layer opposite to the substrate, doping may be performed on the active layer using the gate electrode as a mask.

As shown in FIG. 18 to FIG. 19, an insulating material is deposited on the active layer 120 to form a first gate insulating layer 151; then, a conductive material thin film (the aforementioned first conductive material thin film) is deposited on the first gate insulating layer 151, and a patterning process is performed on the conductive material thin film to form a first gate electrode 131.

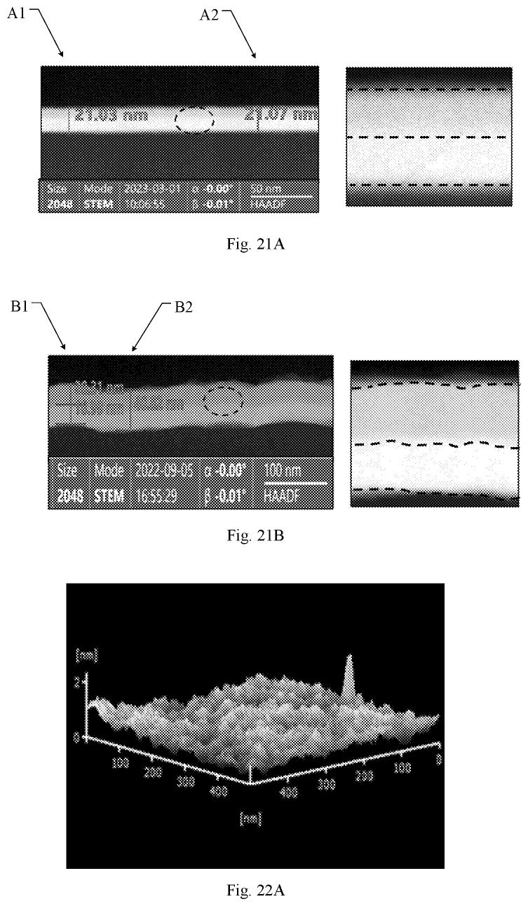

As shown in FIG. 19 to FIG. 20, an insulating material film layer is deposited on the substrate 110 with the first gate electrode 131 formed thereon to form an interlayer dielectric layer 160.

As shown in FIG. 20>and FIG. 4, a patterning process is performed on the interlayer dielectric layer 160 to form via holes; a conductive material thin film is deposited on the interlayer dielectric layer 160, and a patterning process is performed on the conductive material thin film to form a source electrode 141 and a drain electrode 142. The source electrode 141 and the drain electrode 142 are connected to the active layer 120 through the via holes in the interlayer dielectric layer 160.

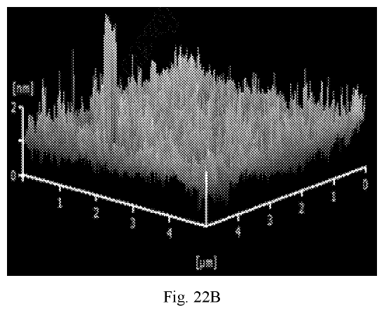

The roughness of a film layer formed by atomic layer deposition is significantly smaller than that of a film layer formed by physical vapor deposition, as detailed below. As shown in FIG. 21A, an IGZO film layer and an IGO film layer are formed by atomic layer deposition. The composition ratio of In, Ga, and Zn in the IGZO film layer is 1:1:1, and the composition ratio of In and Ga in the IGO film layer is 2.5:1. The surfaces of both film layers are very flat, and the sum of their thicknesses ranges from 21.03 nanometers (at position A1) to 21.07 nanometers (at position A2), indicating that the overall thickness of the IGZO and IGO film layers is relatively uniform. As shown in FIG. 21B, an IGZO film layer and an IZO film layer are formed by physical vapor deposition. The composition ratio of In, Ga, and Zn in the IGZO film layer is 1:1:1, and the composition ratio of In and Zn in the IZO film layer is 5:1. The surfaces of the two film layers exhibit significant undulations. At position B1, the thicknesses of the IGZO film layer and the IZO film layer are 18.99 nanometers and 20.31 nanometers, respectively, resulting in a combined thickness of 39.3 nanometers at this position. At position B2, the combined thickness of the IGZO and IZO film layers is 40.82 nanometers. The overall thickness of the IGZO and IZO film layers varies considerably, and the interface between the two film layers has significant defects. As shown in FIG. 22A, a single IGZO film layer is formed by atomic layer deposition. The composition ratio of In, Ga, and Zn in the IGZO film layer is 1:1:1. The height difference from the highest point to the lowest point on the surface of the IGZO film layer is 2.4 nanometers, and the average height variation on the surface is 0.18 nanometers. As shown in FIG. 22B, a single IGZO film layer is formed by physical vapor deposition. The composition ratio of In, Ga, and Zn in the IGZO film layer is 1:1:1. The height difference from the highest point to the lowest point on the surface of the IGZO film layer is 5.1 nanometers, and the average height variation on the surface is 0.3 nanometers. In the above embodiments of the present disclosure, the environmental conditions for physical vapor deposition may be: 5 kW power, 75% oxygen partial pressure; atomic layer deposition is performed at 300 degrees Celsius. For example, in one example, two IGZO film layers are formed based on atomic layer deposition. The composition ratio of In, Ga, and Zn in one IGZO film layer is 1.2:1:1, and the composition ratio of In, Ga, and Zn in the other IGZO film layer is 2.5:1:1. In this case, the surface undulation degree (which can be roughness or used to calculate roughness) of the active layer is approximately 0.77 nanometers. For example, in another example, one IGZO film layer and one IGO film layer are formed based on atomic layer deposition. The composition ratio of In, Ga, and Zn in the IGZO film layer is 1.2:1:1, and the composition ratio of In and Ga in the other IGZO film layer is 2.5:1. In this case, the surface undulation degree (which can be roughness or used to calculate roughness) of the active layer is approximately 0.78 nanometers.

What is claimed is:

1. A thin film transistor, comprising a substrate, and an active layer and a first gate electrode located on the substrate, wherein the active layer comprises a first film layer and a second film layer stacked on the substrate, the second film layer is located between the first film layer and the first gate electrode, and
the first film layer and the second film layer are semiconductor film layers, a mobility of the second film layer is lower than a mobility of the first film layer, and a roughness of the second film layer is smaller than a roughness of the first film layer.

2. The thin film transistor according to claim 1, wherein a material of the first film layer comprises at least one of In, Ga, Zn, and Sn, and the mobility of the first film layer is not less than 20 cm²/Vs; and
a material of the second film layer comprises at least one of In, Ga, and Zn, and the mobility of the second film layer is not greater than 15 cm²/Vs;
the roughness of the first film layer is greater than 1 nanometer, and the roughness of the second film layer is not greater than 1 nanometer.

3. The thin film transistor according to claim 1, wherein an orthographic projection of the first film layer on the substrate coincides with an orthographic projection of the second film layer on the substrate;
the first film layer is in direct contact with the second film layer.

4. The thin film transistor according to claim 1, wherein the active layer is located between the first gate electrode and the substrate, a thickness of the second film layer is less than a thickness of the first film layer, the thickness of the first film layer is 50~500 Å, and the thickness of the second film layer is 10~100 Å; or
the first gate electrode is located between the active layer and the substrate, and an orthographic projection of the active layer on the substrate is located within an orthographic projection of the first gate electrode on the substrate.

5. The thin film transistor according to claim 1, further comprising:
a first gate insulating layer located between the first gate electrode and the active layer.

6. The thin film transistor according to claim 1, further comprising:
a source electrode and a drain electrode, the source electrode and the drain electrode are located on a side of the active layer away from the substrate, and two ends of the active layer are connected to the source electrode and the drain electrode, respectively.

7. The thin film transistor according to claim 6, further comprising a first gate insulating layer and an interlayer dielectric layer, wherein the first gate insulating layer is located between the first gate electrode and the active layer to isolate the first gate electrode and the active layer, and the interlayer dielectric layer is located between the first gate electrode and a source-drain electrode layer to isolate the first gate electrode and the source-drain electrode layer.

8. The thin film transistor according to claim 1, wherein the active layer further comprises:
a third film layer located on a side of the first film layer away from the first gate electrode, the third film layer comprising a semiconductor material;
wherein a mobility of the third film layer is lower than the mobility of the first film layer, and a roughness of the third film layer is smaller than the roughness of the first film layer.

9. The thin film transistor according to claim 8, wherein the first film layer is in direct contact with the third film layer;
a material of the third film layer comprises at least one of In, Ga, and Zn; the mobility of the third film layer is not greater than 15 cm²/Vs;
the roughness of the third film layer is not greater than 1 nanometer;
an orthographic projection of the first film layer on the substrate coincides with an orthographic projection of the third film layer on the substrate.

10. The thin film transistor according to claim 8, further comprising a second gate electrode, wherein the second gate electrode is located on a side of the active layer away from the first gate electrode;
the thin film transistor further comprises a second gate insulating layer, and the second gate insulating layer is located between the second gate electrode and the active layer.

11. The thin film transistor according to claim 1, wherein the thin film transistor further comprises a buffer layer located between the substrate and the active layer.

12. A display panel, comprising the thin film transistor according to claim 1.

13. A method for preparing a thin film transistor, comprising:
providing a substrate;
depositing a first semiconductor material film layer having a first mobility on the substrate at a first film formation rate, and
depositing a second semiconductor material film layer having a second mobility at a second film formation rate, wherein the first mobility is greater than the second mobility, and the first film formation rate is greater than the second film formation rate, such that a roughness of the second semiconductor material film layer is less than a roughness of the first semiconductor material film layer;
patterning the first semiconductor material film layer and the second semiconductor material film layer to respectively form a first film layer and a second film layer; and
depositing a first conductive material film on the substrate, and patterning the first conductive material film to form a first gate electrode, wherein the second film layer is formed between the first film layer and the first gate electrode.

14. The preparation method according to claim 13, wherein the depositing a first semiconductor material film layer having a first mobility on the substrate at a first film formation rate, and depositing a second semiconductor material film layer having a second mobility at a second film formation rate comprises:
forming the first semiconductor material film layer and the second semiconductor material film layer respectively by physical vapor deposition, wherein a power of the physical vapor deposition for forming the first semiconductor material film layer is greater than a power of the physical vapor deposition for forming the second semiconductor material film layer, such that the first film formation rate is greater than the second film formation rate, and a roughness of the second film layer is less than a roughness of the first film layer, the power of the physical vapor deposition for forming the first semiconductor material film layer is 4 KW to 6 KW, and the power of the physical vapor deposition for forming the second semiconductor material film layer is 2 KW to 4 KW.

15. The preparation method according to claim 13, wherein the depositing a first semiconductor material film layer having a first mobility on the substrate at a first film formation rate, and depositing a second semiconductor material film layer having a second mobility at a second film formation rate comprises: forming the first semiconductor material film layer by physical vapor deposition, and forming the second semiconductor material film layer by atomic layer deposition, such that the first film formation rate is greater than the second film formation rate, and a roughness of the second film layer is less than a roughness of the first film layer, the first film formation rate is 80 Å/second to 120 Å/second, and the second film formation rate is 20 Å/second to 60 Å/second.

16. The preparation method according to claim 14, wherein a material of the first film layer comprises at least one of In, Ga, Zn, and Sn, and the mobility of the first film layer is not less than 20 cm²/Vs; and/or, a material of the second film layer comprises at least one of In, Ga, and Zn, and the mobility of the second film layer is not greater than 15 cm²/Vs;
the roughness of the first film layer is greater than 1 nanometer, and the roughness of the second film layer is not greater than 1 nanometer.

17. The preparation method according to claim 13, further comprising:
depositing an insulating material between the first gate electrode and an active layer to form a first gate insulating layer; depositing a conductive material film layer on a side of the active layer away from the substrate, and patterning the conductive material film layer to form a source electrode and a drain electrode, wherein the source electrode and the drain electrode are respectively connected to two ends of the active layer.

18. The preparation method according to claim 13, further comprising:
depositing a third semiconductor material film layer having a third mobility at a third film formation rate, wherein the first mobility is greater than the third mobility, and the first film formation rate is greater than the third film formation rate, such that a roughness of the third semiconductor material film layer is less than the roughness of the first semiconductor material film layer; and
patterning the third semiconductor material film layer to form a third film layer;
the second mobility is equal to the third mobility;
the second film formation rate is equal to the third film formation rate, such that the roughness of the second film layer and a roughness of the third film layer are equal;
a material of the third film layer comprises at least one of In, Ga, and Zn; the mobility of the third film layer is not greater than 15 cm²/Vs;
the roughness of the third film layer is not greater than 1 nanometer;
after depositing the first semiconductor material layer, the second semiconductor material layer, and the third semiconductor material layer, simultaneously performing a patterning process on the first semiconductor material layer, the second semiconductor material layer, and the third semiconductor material layer to form the first film layer, the second film layer, and the third film layer, and causing an orthographic projection of the first film layer on the substrate, an orthographic projection of the second film layer on the substrate, and an orthographic projection of the third film layer on the substrate to coincide.

19. The preparation method according to claim 18, wherein the first gate electrode is formed on a side of the active layer away from the substrate, and the preparation method further comprises:
before forming the active layer and the first gate electrode, depositing a second conductive material thin film on the substrate, and patterning the second conductive material thin film to form a second gate electrode, the preparation method further comprises: before forming the active layer and the first gate electrode and after forming the second gate electrode, depositing an insulating material on the substrate to form a second gate insulating layer to cover the second gate electrode.

20. The preparation method according to claim 18, wherein the first gate electrode is formed between the active layer and the substrate, and the preparation method further comprises:
after forming the first gate electrode and the active layer on the substrate, depositing a second conductive material thin film on the substrate, and patterning the second conductive material thin film to form a second gate electrode, wherein the second gate electrode is formed on a side of the active layer away from the first gate electrode, the preparation method further comprises: after forming the active layer and the first gate electrode and before forming the second gate electrode, depositing an insulating material on the substrate to form a second gate insulating layer.
